(19) United States
(12) Patent Application Publication
(10) Pub. No.: US 2016/0226462 A1
(43) Pub. Date: Aug. 4, 2016

(54) DEVICE AND METHOD FOR DYNAMIC RANGE COMPRESSION OF SOUND

(71) Applicant: Yafit SHEFER, Jerusalem (IL)

(72) Inventor: Mordechai SHEFER, Haifa (IL)

(21) Appl. No.: 15/098,382

(22) Filed: Apr. 14, 2016

Related U.S. Application Data
(63) Continuation-in-part of application No. PCT/IL2015/051019, filed on Oct. 13, 2015.
(60) Provisional application No. 62/075,913, filed on Nov. 6, 2014.

(51) Int. Cl. H03G 7/00; H04R 25/00; H03G 9/18; H04R 3/04

(52) U.S. Cl. CPC H03G 7/004; H04R 3/04; H04R 25/356; H03G 9/18

(57) ABSTRACT

A method compresses the dynamic range of an audio signal. The audio signal is multiplied by a scalar to produce a scalar multiplied version of the audio signal. The audio signal is rectified to produce a rectified version of the audio signal. The rectified version of the audio signal is modified according to a well-defined function to produce a modified rectified version of the audio signal. An output signal is produced based on a ratio between the scalar multiplied version of the audio signal and the modified rectified version of the audio signal. The output signal has a dynamic range less than the dynamic range of the audio signal.

### TECHNICAL FIELD

The present invention relates to processing of sound and, more particularly, to dynamic range compression of sound.

### BACKGROUND OF THE INVENTION

The maximum allowable sound level the human ear can accommodate without damage is 90 db. Normal daily background noise loudness can easily reach 70 db. This implies that if we are to secure safe and sound hearing of some audial content to a person, we must see to it that said content shall be provided between 70 dB and 90 dB loudness levels, which is 20 dB, or factor 120, or about 7 bits in digital terms, of dynamic range (DR). It turns out however that loudness levels that a human can be daily exposed to may exceed 200 dB, which equals 10²⁰ times the minimum audible level of 0 dB, or some 33 bits of DR.

The prior art in DRC of sound commonly consists of 1:1 mappings, such as e.g., logarithmic curves or piecewise linear input-output curves, where the new sample value is determined according to the original sample value only. In those 1:1 mapping the gain for low sound levels is considerably increased on the expense of the gain for high sound levels. This in turn causes a washout effect that is substantially damaging the quality of perception of the verbal, or musical, or whatever content conveyed by a specific sound, in the high loudness levels.

The most acute need of a good audial DRC shows up in hearing aids (HA). There, in order to get a satisfactory hearing at normal background noise loudness, the user has to increase the gain of the HA to levels where positive feedback from speaker to microphone tends to develop, resulting in a dangerously high-power pitch. On the other hand, with the existing sound DRC methods, a person with poor hearing would lose even more in content perception in loud sound due to washout effects.

### SUMMARY OF THE INVENTION

The present invention is a device and method for compressing the dynamic range of sound.

According to an embodiment of the teachings of the present invention there is provided, a method for compressing the dynamic range of an audio signal, the method comprising: (a) multiplying the audio signal by a scalar to produce a scalar multiplied version of the audio signal; (b) rectifying the audio signal to produce a rectified version of the audio signal; (c) modifying the rectified version of the audio signal according to a well-defined function to produce a modified rectified version of the audio signal; and (d) producing an output signal based on a ratio between the scalar multiplied version of the audio signal and the modified rectified version of the audio signal, such that the resulting output signal has a dynamic range less than the dynamic range of the audio signal.

Optionally, the well-defined function is an averaging function.

Optionally, the well-defined function is a maximum value function.

Optionally, the modified rectified version of the audio signal is produced by passing the audio signal through a low pass filter.

Optionally, the multiplied version of the audio signal and the modified rectified version of the audio signal are based on passing the output signal through a feedback loop and multiplying an input signal with the audio signal, and the input signal is based on an output of the feedback loop

Optionally, the dynamic range of the output signal is represented by a first number of bits, and the dynamic range of the audio signal is represented by a second number of bits, and the first number of bits is less than half of the second number of bits.

Optionally, the dynamic range of the audio signal is represented by 33 bits.

Optionally, the dynamic range of the output signal is represented by 7 bits.

There is also provided according to an embodiment of the teachings of the present invention, a method for compressing the dynamic range of an audio signal, comprising: (a) providing a feedback loop coupling an output signal to an input signal, the output signal based in part on each of the audio signal and the feedback loop, the feedback loop including signal rectifying and signal modifying according to a well-defined function; (b) rectifying and modifying the output signal in the feedback loop; (c) subtracting the rectified and modified output signal from a constant value to produce the input signal; and (d) multiplying the audio signal and the input signal to produce the output signal, such that the resulting output signal has a dynamic range less than the dynamic range of the audio signal.

Optionally, the well-defined function is an averaging function.

Optionally, the well-defined function is a maximum value function.

Optionally, the rectifying and the modifying of the output signal in the feedback loop is accomplished by passing the output signal through a low pass filter.

Optionally, the rectifying of the output signal is performed prior to the modifying.

Optionally, a ratio of compression of the dynamic range of the audio signal is given by a ratio between the dynamic range of the audio signal and the dynamic range of the output signal, and the ratio of compression is approximately equal to a ratio between the dynamic range of the audio signal and the dynamic range of a resultant audio signal, the resultant audio signal being the result of processing of the audio signal by a human auditory system.

There is also provided according to an embodiment of the teachings of the present invention, a device for compressing the dynamic range of an audio signal, comprising: (a) a processor coupled to a storage medium, the processor configured to: (i) multiply the audio signal by a scalar to produce a scalar multiplied version of the audio signal; (ii) rectify the audio signal to produce a rectified version of the audio signal; (iii) modify the rectified version of the audio signal according to a well-defined function to produce a modified rectified version of the audio signal; and (iv) produce an output signal based on a ratio between the scalar multiplied version of the audio signal and the modified rectified version of the audio signal, such that the resulting output signal has a dynamic range less than the dynamic range of the audio signal.

Optionally, the device further comprises: (b) a hearing aid housing for fitting in the ear of a user, and the processor is positioned within the hearing aid housing.

Optionally, the well-defined function is selected from the group consisting of: an averaging function, and a maximum value function.

Optionally, the modified rectified version of the audio signal is produced by passing the audio signal through a low pass filter.

Optionally, the multiplied version of the audio signal and the modified rectified version of the audio signal are based on passing the output signal through a feedback loop and multiplying an input signal with the audio signal, and wherein the input signal is based on an output of the feedback loop.

Optionally, the dynamic range of the output signal is represented by a first number of bits, and the dynamic range of the audio signal is represented by a second number of bits, and the first number of bits is less than half of the second number of bits.

There is also provided according to an embodiment of the teachings of the present invention, a device for compressing the dynamic range of an audio signal, comprising: (a) a processor coupled to a storage medium, the processor configured to: (i) provide a coupling of an output signal to an input signal via a feedback loop, the output signal based in part on each of the audio signal and the feedback loop; (ii) rectify the output signal in the feedback loop; (iii) modify the rectified output signal in the feedback loop according to a well-defined function; (iv) subtract the rectified and modified output signal from a constant value to produce the input signal; and (v) multiply the audio signal and the input signal to produce the output signal, such that the resulting output signal has a dynamic range less than the dynamic range of the audio signal.

There is also provided according to an embodiment of the teachings of the present invention, a non-transitory computer-readable storage medium having embedded thereon computer-readable code for causing a suitably programmed system to compress the dynamic range of an audio signal, by performing the following steps when such program is executed on the system. The steps comprise: (a) multiplying the audio signal by a scalar to produce a scalar multiplied version of the audio signal; (b) rectifying the audio signal to produce a rectified version of the audio signal; (c) modifying the rectified version of the audio signal according to a well-defined function to produce a modified rectified version of the audio signal; and (d) producing an output signal based on a ratio between the scalar multiplied version of the audio signal and the modified rectified version of the audio signal, such that the resulting output signal has a dynamic range less than the dynamic range of the audio signal.

There is also provided according to an embodiment of the teachings of the present invention, a non-transitory computer-readable storage medium having embedded thereon computer-readable code for causing a suitably programmed system to compress the dynamic range of an audio signal, by performing the following steps when such program is executed on the system. The steps comprise: (a) providing a feedback loop coupling an output signal to an input signal, the output signal based in part on each of the audio signal and the feedback loop, the feedback loop including signal rectifying and signal modifying according to a well-defined function; (b) rectifying and modifying the output signal in the feedback loop; (c) subtracting the rectified and modified output signal from a constant value to produce the input signal; and (d) multiplying the audio signal and the input signal to produce the output signal, such that the resulting output signal has a dynamic range less than the dynamic range of the audio signal.

### BRIEF DESCRIPTION OF THE DRAWINGS

The invention is herein described, by way of example only, with reference to the accompanying drawings, wherein:

FIG. 1 is a neuromorphic dynamic range compression process using a feedback-automatic gain control (fb-AGC) model that takes place in biological neuro-sensory systems according to an embodiment of the invention;

FIG. 2 is a description of the 2-input transmission of the signal multiplier of FIG. 1;

FIG. 3 is a graph of the fb-AGC model average transmission, also known as Weber's Law. The average output asymptotically converges to K when the input goes to infinity, and converges to a straight line whose slope is K when the input goes to zero;

FIG. 4 describes the response of the fb-AGC model to an evenly spaced staircase input signal;

FIG. 5 is a schematic diagram of a generalized representation of an exemplary processing unit for performing dynamic range compression according to an embodiment of the invention.

### DESCRIPTION OF THE PREFERRED EMBODIMENTS

The present invention is a device and method for compressing the dynamic range of sound.

The principles and operation of the device and method according to the present invention may be better understood with reference to the drawings and the accompanying description.

Before explaining at least one embodiment of the invention in detail, it is to be understood that the invention is not necessarily limited in its application to the details of construction and the arrangement of the components and/or methods set forth in the following description and/or illustrated in the drawings and/or the examples. The invention is capable of other embodiments or of being practiced or carried out in various ways.

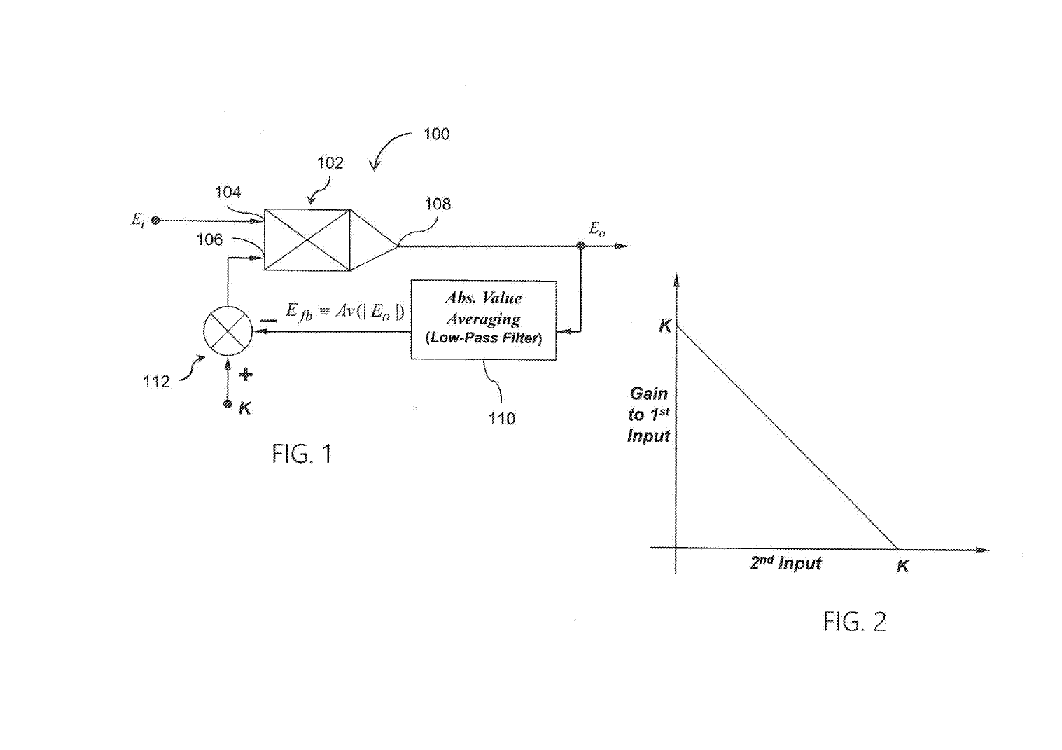

Referring now to the drawings, FIG. 1 is an embodiment of a DRC device and method according to a neuromorphic fb-AGC model 100. In the neuromorphic fb-AGC model, each sample of an acquired sound signal Eᵢ is input to a first input 104 of a signal multiplier 102. The sound signal Eᵢ is interchangeably referred to as an audio signal. The signal multiplier 102 has an output 108, which is fed back, via a feedback loop, into a second input 106 of the signal multiplier 102. The output 108 of the signal multiplier 102 is rectified, i.e., only the absolute value of the signal multiplier output is regarded, and modified in the feedback loop, and subtracted 112 from a constant K before being input into the second input 106 of the signal multiplier 102. The signals which are input into the first input 104 and the second input 106 are multiplied in order to generate the output 108.

The modifying performed during the rectification and modification operation is performed on the basis of any well-defined function of the rectified signal. In an exemplary non-limiting implementation, the well-defined function is an averaging function which averages the time samples of the rectified signal. In such an implementation, the rectifying and modifying may be performed by passing the output 108 of the signal multiplier 102 through a low pass filter 110 which rectifies and averages the output 108 of the signal multiplier 102. In an alternative non-limiting implementation, the well-defined function is a maximizing function which outputs the maximum value or values of the rectified signal samples in a selected vicinity of a currently processed rectified signal sample. Although the Figures and the remaining sections of the present disclosure describe the present embodiments of the DRC device within the context of the rectifying and averaging performed by the LPF 110, other embodiments based on alternative well-defined functions, such as, for example, the above mentioned maximizing function, should be apparent to one of ordinary skill in the art.

The average transmission (DC) of the neuromorphic fb-AGC model 100 can be calculated by assuming a constant input level for which: Av(E_{O})≡Ē_{O} and Av(Eᵢ)≡Ēᵢ. This yields: Ē_{O}=Ēᵢ (K−Ē_{O}), therefore:

$${\overline{E}}_{o} = \frac{K {\overline{E}}_{i}}{1 + {\overline{E}}_{i}} ,$$

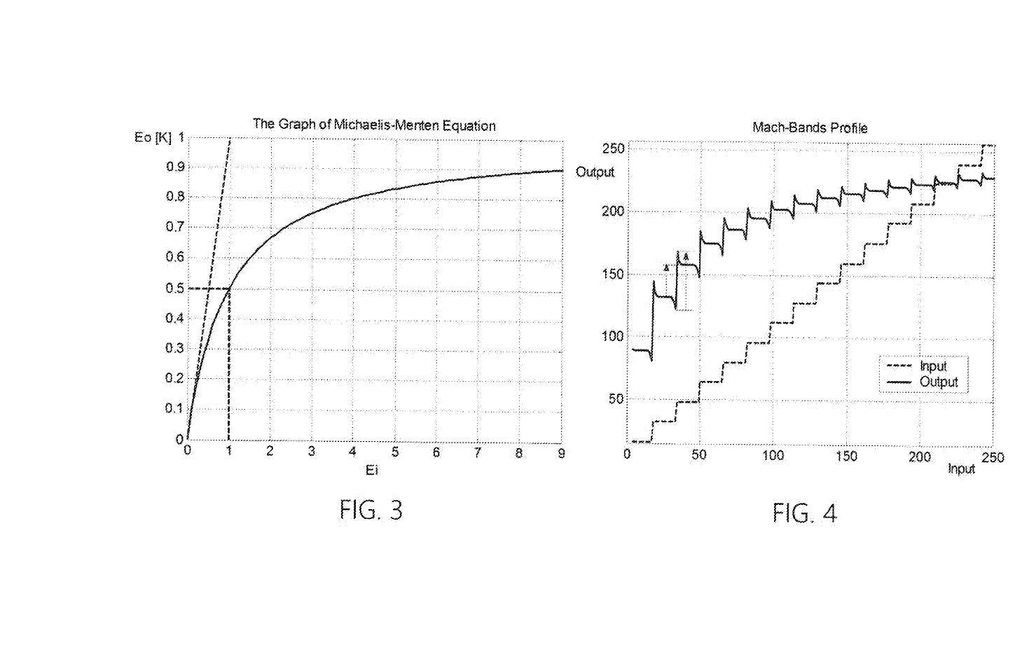

which is known as a Michaelis-Menten Equation, the graph of which is described in FIG. 3. According to the graph in FIG. 3, the average output asymptotically converges to K when the input goes to infinity, and the average output converges to a straight line with slope K when the input goes to zero. The DR compression ratio (CR) is defined as the ratio between the output and the input when the input is a full-scale input FSᵢ, assuming FSᵢ>>1. This can be expressed as:

$$CR ≡ \frac{K}{{FS}_{i}} .$$

The DR compression ratio is thus readily controlled by the parameter K.

The fb-AGC gain for variations of low frequencies (“DC-gain”) is given by:

$${G}_{DC} ≡ \frac{d {\overline{E}}_{o}}{d {\overline{E}}_{i}} = \frac{d}{d {\overline{E}}_{i}} ( \frac{K {\overline{E}}_{i}}{1 + K {\overline{E}}_{i}} ) = \frac{K}{{( 1 + K {\overline{E}}_{i} )}^{2}} .$$

The fb-AGC gain for instantaneous loudness variations (“AC-gain”) is obtained by assuming that for such variations, the LPF 110 output E_{fb} remains constant, i.e., E_{fb}=Ē_{O}. Accordingly, the AC-gain can be expressed as

$${G}_{AC} ≡ \frac{d {E}_{o}}{d {E}_{i}} {\vert}_{{E}_{fb} = {\overline{E}}_{o}} = K - {\overline{E}}_{o} = K ( 1 - \frac{{\overline{E}}_{i}}{1 + {\overline{E}}_{i}} ) = \frac{K}{1 + K {\overline{E}}_{i}} .$$

The ratio between the AC-gain and the DC-gain can thus be expressed as: G_{AC}/G_{DC}=1+KĒᵢ. Regarding the quotient G_{AC}/G_{DC} as a measure of the high frequencies (HF) enhancement of the neuromorphic DRC, an observation is made that the amount of the HF enhancement, or the “effective audial bandwidth”, increases linearly with the average loudness of the perceived sound. The linear increase in effective audial bandwidth with respect to the average loudness of perceived sound is a well-known property of human sensory systems.

As a byproduct, the magnitude of an incremental change in an input stimulus ΔEᵢ|_{Th} such that the corresponding output just reaches a given perception-threshold Th, is calculated. The results of such a calculation are readily available from the AC-gain expression above, and can be expressed as:

$$Δ {E}_{i} {\vert}_{Th} = ( \frac{1}{K} + {\overline{E}}_{i} ) \cdot Th ,$$

namely the input increment magnitude needed to cause the output to just reach a constant perception threshold is affine-proportional to the average input level. This is known as the modified Weber's Law that characterizes the gross-transmissions of human neuro-sensory systems.

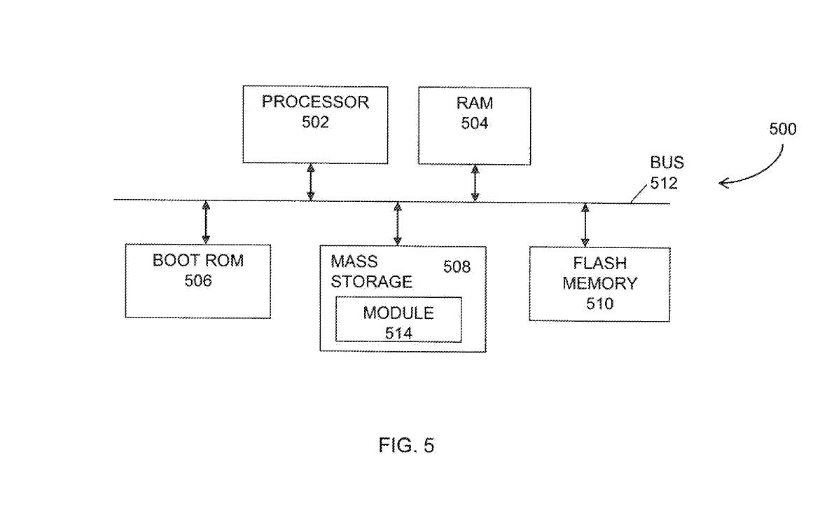

Refer now to FIG. 4, the response of the fb-AGC to an even staircase signal. The average transmission comes out according to the Michaelis-Menten equation, whereas each intra-steps transition is accompanied by a doublet, consisting of a leading undershoot and a trailing overshoot. The undershoots and overshoots generate the well-known Mach-Bands illusion in vision. The difference between two adjacent output horizontal segments relative to the input step-size, reflects the DC-gain (G_{DC}) of the fb-AGC transmission, whereas the amplitude of the output doublet that corresponds to the input step, again relative to the input step-size, reflects the AC-gain (G_{AC}) of the fb-AGC transmission. As analytically derived above, the ratio G_{AC}/G_{DC} of the two gains grows linearly with the input level.

According to another embodiment of DRC, the averaging operation as described in FIG. 1 is performed according to: E_{fb}=W(|E_{O}|), where W is an appropriate averaging matrix and E_{O} and E_{fb} are vectors. The notation: |V| relates to a vector whose entries are the absolute values of the corresponding entries of V. With K being a scalar of arbitrary positive value, and by applying vector-matrix algebra, the resulting output can be expressed as:

$${E}_{o} = \frac{{KE}_{i}}{1 + W ( \vert {E}_{i} \vert )} ,$$

where Eᵢ is the input signal vector. The term |Eᵢ| is referred to as the rectified version of Eᵢ (only the absolute value of Eᵢ is regarded). This is the accurate single-step closed-form solution of the fb-AGC response to any input vector. As a result, the closed-form solution provides a significant advantage in realization relative to other possible solutions. An example of an appropriate averaging matrix is:

$$W ≡ \frac{1}{3} [ \begin{matrix}1 & 1 & 0 & 0 & 0 \\ 1 & 1 & 1 & 0 & 0 \\ 0 & 1 & 1 & 1 & 0 \\ 0 & 0 & 1 & 1 & 1 \\ 0 & 0 & 0 & 1 & 1\end{matrix} ]$$

The scalar K is a parameter that governs the DRC ratio.

Note that as a result of the above described input-output relationship, a high dynamic range compression ratio is achievable. For example, the dynamic range of the input sound can be represented by approximately 33 bits, whereas the dynamic range of the output can be represented by approximately 7 bits, resulting in a dynamic range compression ratio of 33/7. The resulting dynamic range compression maintains the integrity of the information contained in the original input sound. As previously described, the number of bits used to represent the dynamic range of the output is adjustable based in part on the controlled parameter K. Furthermore, as a byproduct of the above mentioned well-known property of human sensory systems, the dynamic range compression ratio is the same or similar to the dynamic range compression achieved by the processing of sound by a human auditory system.

The above described embodiments of the DRC device and method can be implemented and/or executed on a processing unit. Refer now to FIG. 5, a high-level partial block diagram of an exemplary processing unit 500 configured to implement the DRC functionality and methodology as previously described. Processing unit 500 includes a processor 502 (one or more) and four exemplary memory devices: a RAM 504, a boot ROM 506, a mass storage device (hard disk) 508, a flash memory 510, all communicating via a common bus 512. As is known in the art, processing and memory can include any computer readable medium storing software and/or firmware and/or hardware element(s) including, but not limited to, field programmable logic array (FPLA) element(s), hard-wired logic element(s), field programmable gate array (FPGA) element(s), and application-specific integrated circuit (ASIC) element(s). Any instruction set architecture may be used in the processor 502 including, but not limited to, reduced instruction set computer (RISC) architecture and/or complex instruction set computer (CISC) architecture. The processor 502 can be any number of computer processors, including, but not limited to a microprocessor, an ARM processor, an ASIC, a DSP, a state machine, and a microcontroller. A module (processing module) 514 is shown on the mass storage device 508, but as will be obvious to one skilled in the art, could be located on any of the memory devices.

The mass storage device 508 is a non-limiting example of a non-transitory computer-readable storage medium bearing computer-readable code for implementing the DRC methodology described herein. Other examples of such computer-readable storage media include read-only memories such as CDs bearing such code. The processing unit 500 may have an operating system stored on the memory devices, the ROM 506 may include boot code for the system, and the processor 502 may be configured for executing the boot code to load the operating system to the RAM 504, executing the operating system to copy computer-readable code to the RAM 504.

In a non-limiting implementation, the processing unit 500, or a subset of the components of the processing unit 500, is embedded in a housing or casing of a small-scale appliance, such as, for example, a hearing aid device. Such an exemplary hearing device is configured to fit in the ear of user in the normal way. Accordingly, such a hearing aid device performs the DRC functionality and methodology as previously described.

Implementation of the device and/or method of embodiments of the invention can involve performing or completing selected tasks manually, automatically, or a combination thereof. Moreover, according to actual instrumentation and equipment of embodiments of the device and/or method of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of device and/or method as described herein are performed by a data processor, such as a computing platform for executing a plurality of instructions. Optionally, the data processor includes a volatile memory for storing instructions and/or data and/or a non-volatile storage, for example, non-transitory storage media such as a magnetic hard-disk and/or removable media, for storing instructions and/or data.

For example, any combination of one or more non-transitory computer readable (storage) medium(s) may be utilized in accordance with the above-listed embodiments of the present invention. The non-transitory computer readable (storage) medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

As will be understood with reference to the paragraphs and the referenced drawings, provided above, various embodiments of computer-implemented methods are provided herein, some of which can be performed by various embodiments of apparatuses and systems described herein and some of which can be performed according to instructions stored in non-transitory computer-readable storage media described herein. Still, some embodiments of computer-implemented methods provided herein can be performed by other apparatuses or systems and can be performed according to instructions stored in computer-readable storage media other than that described herein, as will become apparent to those having skill in the art with reference to the embodiments described herein. Any reference to systems and computer-readable storage media with respect to the following computer-implemented methods is provided for explanatory purposes, and is not intended to limit any of such systems and any of such non-transitory computer-readable storage media with regard to embodiments of computer-implemented methods described above. Likewise, any reference to the following computer-implemented methods with respect to systems and computer-readable storage media is provided for explanatory purposes, and is not intended to limit any of such computer-implemented methods disclosed herein.

The block diagrams in the Figures illustrate the architecture, functionality, and operation of possible implementations of systems, methods and computer program products according to various embodiments of the present invention. In this regard, each block in the block diagrams may represent a module, segment, or portion of code, which comprises one or more executable instructions for implementing the specified logical function(s). It will also be noted that each block of the block diagrams, and combinations of blocks in the block diagrams, can be implemented by special purpose hardware-based systems that perform the specified functions or acts, or combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the singular form “a”, “an” and “the” include plural references unless the context clearly dictates otherwise.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

The above-described processes including portions thereof can be performed by software, hardware and combinations thereof. These processes and portions thereof can be performed by computers, computer-type devices, workstations, processors, micro-processors, other electronic searching tools and memory and other non-transitory storage-type devices associated therewith. The processes and portions thereof can also be embodied in programmable non-transitory storage media, for example, compact discs (CDs) or other discs including magnetic, optical, etc., readable by a machine or the like, or other computer usable storage media, including magnetic, optical, or semiconductor storage, or other source of electronic signals. The processes (methods) and systems, including components thereof, herein have been described with exemplary reference to specific hardware and software. The processes (methods) have been described as exemplary, whereby specific steps and their order can be omitted and/or changed by persons of ordinary skill in the art to reduce these embodiments to practice without undue experimentation. The processes (methods) and systems have been described in a manner sufficient to enable persons of ordinary skill in the art to readily adapt other hardware and software as may be needed to reduce any of the embodiments to practice without undue experimentation and using conventional techniques.

It will be appreciated that the above descriptions are intended only to serve as examples, and that many other embodiments are possible within the scope of the present invention as defined in the appended claims.

What is claimed is:

1. A method for compressing the dynamic range of an audio signal, the method comprising:
(a) multiplying the audio signal by a scalar to produce a scalar multiplied version of the audio signal;
(b) rectifying the audio signal to produce a rectified version of the audio signal;
(c) modifying the rectified version of the audio signal according to a well-defined function to produce a modified rectified version of the audio signal; and
(d) producing an output signal based on a ratio between the scalar multiplied version of the audio signal and the modified rectified version of the audio signal, such that the resulting output signal has a dynamic range less than the dynamic range of the audio signal.

2. The method of claim 1, wherein the well-defined function is an averaging function.

3. The method of claim 1, wherein the well-defined function is a maximum value function.

4. The method of claim 1, wherein the modified rectified version of the audio signal is produced by passing the audio signal through a low pass filter.

5. The method of claim 1, wherein the multiplied version of the audio signal and the modified rectified version of the audio signal are based on passing the output signal through a feedback loop and multiplying an input signal with the audio signal, and wherein the input signal is based on an output of the feedback loop.

6. The method of claim 1, wherein the dynamic range of the output signal is represented by a first number of bits, and the dynamic range of the audio signal is represented by a second number of bits, and the first number of bits is less than half of the second number of bits.

7. The method of claim 1, wherein the dynamic range of the audio signal is represented by 33 bits.

8. The method of claim 1, wherein the dynamic range of the output signal is represented by 7 bits.

9. A method for compressing the dynamic range of an audio signal, comprising:
(a) providing a feedback loop coupling an output signal to an input signal, the output signal based in part on each of the audio signal and the feedback loop, the feedback loop including signal rectifying and signal modifying according to a well-defined function;
(b) rectifying and modifying the output signal in the feedback loop;
(c) subtracting the rectified and modified output signal from a constant value to produce the input signal; and
(d) multiplying the audio signal and the input signal to produce the output signal, such that the resulting output signal has a dynamic range less than the dynamic range of the audio signal.

10. The method of claim 9, wherein the well-defined function is an averaging function.

11. The method of claim 9, wherein the well-defined function is a maximum value function.

12. The method of claim 9, wherein the rectifying and the modifying of the output signal in the feedback loop is accomplished by passing the output signal through a low pass filter.

13. The method of claim 9, wherein the rectifying of the output signal is performed prior to the modifying.

14. The method of claim 9, wherein a ratio of compression of the dynamic range of the audio signal is given by a ratio between the dynamic range of the audio signal and the dynamic range of the output signal, and wherein the ratio of compression is approximately equal to a ratio between the dynamic range of the audio signal and the dynamic range of a resultant audio signal, the resultant audio signal being the result of processing of the audio signal by a human auditory system.

15. A device for compressing the dynamic range of an audio signal, comprising:
(a) a processor coupled to a storage medium, the processor configured to:
(i) multiply the audio signal by a scalar to produce a scalar multiplied version of the audio signal;
(ii) rectify the audio signal to produce a rectified version of the audio signal;
(iii) transform the rectified version of the audio signal according to a well-defined function to produce a modified rectified version of the audio signal; and
(iv) produce an output signal based on a ratio between the scalar multiplied version of the audio signal and the modified rectified version of the audio signal, such that the resulting output signal has a dynamic range less than the dynamic range of the audio signal.

16. The device of claim 15, further comprising:
(b) a hearing aid housing for fitting in the ear of a user, wherein the processor is positioned within the hearing aid housing.

17. The device of claim 15, wherein the well-defined function is selected from the group consisting of an averaging function, and a maximum value function.

18. The device of claim 15, wherein the modified rectified version of the audio signal is produced by passing the audio signal through a low pass filter.

19. The device of claim 15, wherein the multiplied version of the audio signal and the modified rectified version of the audio signal are based on passing the output signal through a feedback loop and multiplying an input signal with the audio signal, and wherein the input signal is based on an output of the feedback loop.

20. The device of claim 15, wherein the dynamic range of the output signal is represented by a first number of bits, and the dynamic range of the audio signal is represented by a second number of bits, and the first number of bits is less than half of the second number of bits.
